(19) United States
(12) Patent Application Publication
(10) Pub. No.: US 2024/0431104 A1
(43) Pub. Date: Dec. 26, 2024

(54) SEMICONDUCTOR STORAGE DEVICE AND METHOD OF MANUFACTURING THE SAME

(71) Applicant: Kioxia Corporation, Tokyo (JP)

(72) Inventors: Junichi KANEYAMA, Yokkaichi Mie (JP); Tatsunori ISOGAI, Yokkaichi Mie (JP)

(21) Appl. No.: 18/745,594

(22) Filed: Jun. 17, 2024

(30) Foreign Application Priority Data
Jun. 20, 2023 (JP) 2023-100984

(51) Int. Cl. H10B 43/27; H10B 43/10; H10B 43/35

(52) U.S. Cl. CPC H10B 43/27; H10B 43/10; H10B 43/35

(57) ABSTRACT

A semiconductor storage device includes a stacked body in which electrode layers and first insulation layers are alternately stacked in a first direction. A semiconductor layer extends through the stacked body in the first direction. A second insulation layer is provided between the stacked body and the semiconductor layer. A third insulation layer is provided between the stacked body and the second insulation layer. A first thickness of the third insulation layer between the electrode layers and the second insulation layer is thicker than a second thickness of the third insulation layer between the first insulation layers and the second insulation layer. Fourth insulation layers are provided between the electrode layers and the third insulation layer. A fifth insulation layer is provided between an electrode layer and the first insulation layers adjacent to the electrode layer and between the electrode layer and one of the fourth insulation layers.

### CROSS-REFERENCE TO RELATED APPLICATION(S)

This application is based upon and claims the benefit of priority from Japanese Patent Application No. 2023-100984, filed Jun. 20, 2023, the entire contents of which are incorporated herein by reference.

### FIELD

Embodiments described herein relate generally to a semiconductor storage device and a method for manufacturing the same.

### BACKGROUND

A NAND flash memory in which memory cells are three-dimensionally arranged is known as one type of semiconductor storage device.

### BRIEF DESCRIPTION OF THE DRAWINGS

FIG. 1 is a cross-sectional view illustrating a configuration example of a semiconductor storage device according to a first embodiment.

FIG. 2 is a schematical plane view illustrating a stacked body in the semiconductor storage device according to the first embodiment.

FIG. 3 illustrates a vertical cross-section of a portion of a memory cell array in the semiconductor storage device according to the first embodiment.

FIG. 4 illustrates a horizontal cross-section of a memory pillar region of the memory cell array.

FIG. 5 illustrates another horizontal cross-section of the memory pillar region of the memory cell array.

FIG. 6 illustrates a vertical cross-section of another portion of the memory cell array.

FIGS. 7-15 are cross-sectional views illustrating an example of a method of manufacturing an array chip of the semiconductor storage device according to the first embodiment.

FIG. 16 is a cross-sectional view illustrating an example of a method of manufacturing an array chip of a semiconductor storage device according to a second embodiment.

### DETAILED DESCRIPTION

Embodiments provide a semiconductor storage device capable of preventing reduction in unintended current flowing in a memory cell of the semiconductor storage device, and a method of manufacturing the semiconductor storage device.

In general, according to one embodiment, a semiconductor storage device according to the present embodiment includes a stacked body in which electrode layers and first insulation layers are alternately stacked in a first direction. A semiconductor layer extends through the stacked body in the first direction. A second insulation layer extends in the first direction and is provided between the stacked body and the semiconductor layer. A third insulation layer extends in the first direction and is provided between the stacked body and the second insulation layer. A first thickness of the third insulation layer in a second direction perpendicular to the first direction between the electrode layers and the second insulation layer is thicker than a second thickness of the third insulation layer in a second direction perpendicular to the first direction between the first insulation layers and the second insulation layer. The third insulation layer is inclined with respect to the first direction in a step region of the third insulation layer where the thickness thereof changes from the first thickness to the second thickness. Fourth insulation layers are provided between the electrode layers and the third insulation layer. A fifth insulation layer is provided between a first electrode layer which is one of the electrode layers, and the first insulation layers adjacent to the first electrode layer and between the first electrode layer and one of the fourth insulation layers.

Hereinafter, embodiments according to the present disclosure will be described with reference to the drawings. The present embodiment does not limit the scope of the present disclosure. The drawings are schematic and conceptual. In the specification and drawings, the same elements will be denoted by the same reference signs.

### First Embodiment

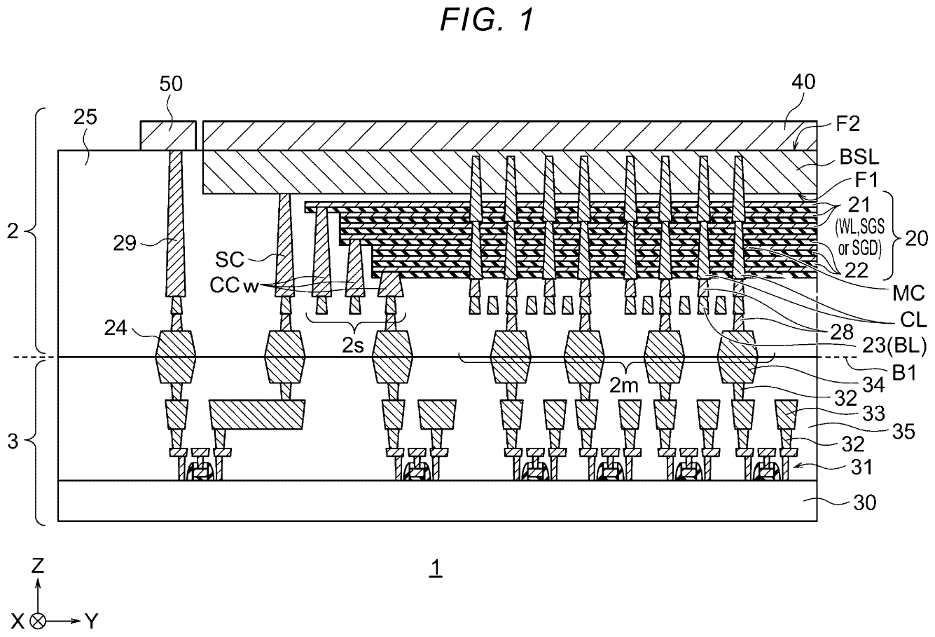

FIG. 1 is a cross-sectional view illustrating a configuration example of a semiconductor storage device 1 according to a first embodiment. Hereinafter, a stacking direction of a stacked body 20 is defined as a Z direction.

One direction intersecting with, for example, orthogonal to the Z direction is defined as a Y direction. One direction intersecting with, for example, orthogonal to each of the Z direction and the Y direction is defined as a X direction.

The semiconductor storage device 1 includes an array chip 2 having a memory cell array and a CMOS chip 3 having a CMOS circuit. The array chip 2 and the CMOS chip 3 are bonded to each other on a bonding surface B1 and electrically connected to each other via wirings joined on the bonding surface. FIG. 1 illustrates a state in which the array chip 2 is mounted on the CMOS chip 3.

The CMOS chip 3 includes a substrate 30, transistors 31, vias 32, wirings 33 and 34, and an interlayer insulation layer 35.

The substrate 30 is, for example, a semiconductor substrate such as a silicon substrate. The transistors 31 are NMOS or PMOS transistors provided on the substrate 30. The transistors 31 make up the CMOS circuit that controls the memory cell array of the array chip 2, for example. The transistors 31 make up a logical circuit such as a sense amplifier, a row decoder, and a column decoder. Semiconductor elements such as a resistive element and a capacitive element other than the transistors 31 may be formed on the substrate 30.

The vias 32 electrically connect the transistors 31 to the wirings 33 and the wirings 33 to the wirings 34. The wirings 33 and 34 make up a multilayer wiring structure in the interlayer insulation layer 35. The wirings 34 are embedded in the interlayer insulation layer 35, substantially flush with an upper surface of the interlayer insulation layer 35, and exposed at the upper surface of the interlayer insulation layer 35. The wirings 33 and 34 are electrically connected to the transistors 31 or the like. For the vias 32 and the wirings 33 and 34, for example, a low resistance metal such as copper or tungsten is used. The interlayer insulation layer 35 covers and protects the transistors 31, the vias 32, the wirings 33, and the wirings 34. For the interlayer insulation layer 35, for example, an insulation layer such as a silicon oxide film including silicon and oxygen is used.

The array chip 2 includes the stacked body 20, a columnar bodies CL, a source layer BSL, a metal layer 40, contact plugs CCw, a contact plug 29, and a bonding pad 50.

The stacked body 20 is provided above the transistors 31 and located in the Z direction with respect to the substrate 30. The stacked body 20 has an alternately stacked electrode layers 21 and insulation layers 22 along the Z direction. The stacked body 20 makes up the memory cell array having a plurality of memory cells MC. For the electrode layers 21, a conductive metal such as tungsten is used. For the insulation layers 22, an insulation layer such as a silicon oxide film including silicon and oxygen is used. The insulation layers 22 insulate the electrode layers 21 from one another. Any number of the electrode layers 21 and the insulation layers 22 may be stacked. The insulation layer 22 may be, for example, a porous insulation layer or even an air gap.

One or a plurality of electrode layers 21 at the upper end and the lower end of the stacked body 20 in the Z direction functions as a source side select gate SGS and a drain side select gate SGD. The electrode layers 21 between the source side select gate SGS and the drain side select gate SDG functions as word lines WL. A gate electrode of each memory cell MC is provided by one of the word lines WL. The drain side select gate SGD is a gate electrode of a drain side select transistor. The source side select gate SGS is a gate electrode of a source side select transistor and provided in an upper region of the stacked body 20. The drain side select gate SGD is provided in a lower region of the stacked body 20. In FIG. 1, the array chip 2 is inverted so as to be bonded with the CMOS chip 3. Therefore, the lower and upper regions of the stacked body 20 shown on the upper and lower sides of FIG. 1, respectively. Therefore, the upper region of the stacked body 20 is closer to the CMOS chip 3 than the lower region of the stacked body 20.

The semiconductor storage device 1 has a plurality of the memory cells MC connected in series between a source side select transistor and the drain side select transistor. A structure in which the source side select transistor, the memory cell MC, and the drain side select transistor are connected to each other in series is called a “memory string” or a “NAND string”. Each memory string is connected to a corresponding bit line BL through a via 28, for example. The bit line BL is a wiring 23 provided above the stacked body 20 and extending in the X direction.

In the stacked body 20, a plurality of the columnar bodies CL is provided. Each columnar body CL extends in the stacked body 20 to penetrate the stacked body 20 in the stacking direction (Z direction) of the stacked body 20 and extends from the via 28 connected to the bit line BL to the source layer BSL. The internal structure of the columnar body CL will be described later. In the present embodiment, the columnar body CL has a high aspect ratio, and thus the columnar body CL is divided into two tiers in the Z direction. However, the columnar body CL may have just one tier and may be divided into three or more tiers.

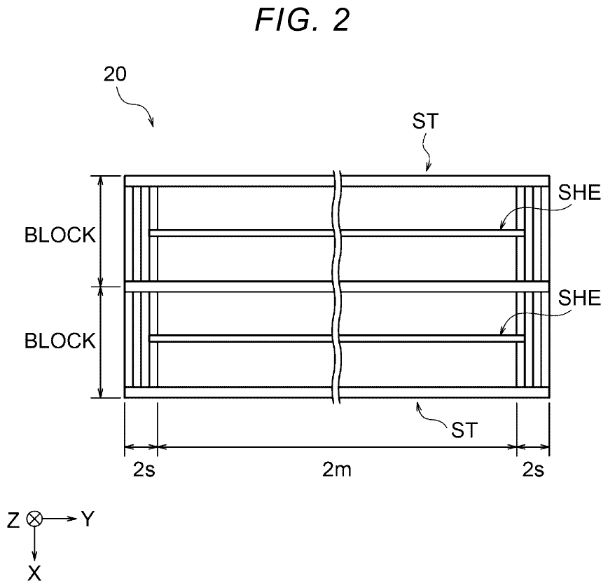

In addition, although not illustrated in FIG. 1, in the stacked body 20, a plurality of the slits ST (see FIG. 2) is provided. Each slit ST extends in the Y direction and penetrates the stacked body 20 in the stacking direction (Z direction) of the stacked body 20. The slit ST is filled with an insulation material such as a silicon oxide film including silicon and oxygen and the slit ST has a plate shape. The slit ST electrically isolates the electrode layers 21 of the stacked body 20 that are on either side of the slit ST. Alternatively, the insulation layer such as a silicon oxide film may be covered on the inner wall of the slit ST and then, a conductive material may be embedded in the inside of the insulation layer. In such a case, the conductive material also functions as a source wiring reaching the source layer BSL.

Above the stacked body 20, the source layer BSL is provided. The source layer BSL has a first surface F1 and a second surface F2 on opposite sides thereof in the Z direction. The stacked body 20 is provided on the first surface F1 side of the source layer BSL and the metal layer 40 is provided on the second surface F2 side. The source layer BSL is connected to one ends of the plurality of columnar bodies CL in common and provides a source voltage that is common to the plurality of columnar bodies CL in the same memory cell array. That is, the source layer BSL functions as a common source electrode of the memory cell array. For the source layer BSL, a conductive material such as doped polysilicon is used. For the metal layer 40, a metal material having lower resistance than that of the source layer BSL such as copper, aluminum, or tungsten is used.

The bonding pad 50 is provided in a region above the stacked body 20 where the source layer BSL is not provided. The bonding pad 50 is connected to a metal wire or the like (not illustrated), and receives power supply or a signal from the outside of the semiconductor storage device 1. The bonding pad 50 is connected to one end of the contact plug 29 in the Z direction. The bonding pad 50 is connected to the transistors 31 of the CMOS chip 3 via the contact plug 29, the wiring 24, and the wiring 34. Accordingly, an external power source supplied from the bonding pad 50 is supplied to the transistor 31. Alternatively, signals are supplied to the transistors 31 or the memory cell array via the bonding pad 50.

The contact plugs CCw are provided on the periphery of the stacked body 20, and extends through an interlayer insulation layer 25 in the Z direction. The contact plug CCws are electrically connected between the electrode layers 21 and the wirings 24. The contact plugs CCw are provided in a stepped portion 2s (see FIG. 2) formed at the end part of the stacked body 20 in a step-like shape, and each is electrically connected to a respective electrode layer 21. Each contact plug CCw is provided for transmitting a word line voltage from the CMOS chip 3 to the respective electrode layer 21. For the contact plugs CCw, a low resistance metal such as copper or tungsten is used.

The contact plug 29 is provided on the periphery of the stacked body 20, and extends through the interlayer insulation layer 25 in the Z direction. The contact plug 29 is a contact plug extending from one of the wirings 24 to the bonding pad 50.

The contact plug 29 is electrically connected between the bonding pad 50 and one of the wirings 24. The contact plug 29 is used for supplying a power supply voltage or signals from the bonding pad 50 to the array chip 2 or the CMOS chip 3. For the contact plug 29, a low resistance metal such as copper or tungsten is used. The power supply voltage may be a power supply voltage VDD having a high-level voltage or a reference voltage (for example, a ground voltage) VSS having a low-level voltage. The signal may be a control signal from the outside, and may be write data or read data.

In the present embodiment, the array chip 2 and the CMOS chip 3 are formed separately and bonded to each other on the bonding surface B1. Therefore, the transistors for controlling the memory cell array are not provided in the array chip 2. In addition, the memory cell array is not provided in the CMOS chip 3. Both the transistors 31 and the stacked body 20 are located at the first surface F1 side of the source layer BSL. The transistors 31 are located at the side opposite to the second surface F2 of the source layer BSL on which the metal layer 40 is located.

The vias 28, the wirings 23, and the wirings 24 are provided above the stacked body 20. The wirings 23 and 24 are embedded in the interlayer insulation layer 25. The wirings 24 are substantially flush with the upper surface of the interlayer insulation layer 25 and exposed at the upper surface of the interlayer insulation layer 25. The wirings 23 and 24 are electrically connected to semiconductor bodies 210 of the columnar bodies CL or the like. For the vias 28, the wirings 23, and the wirings 24, a low resistance metal such as copper or tungsten is used. The interlayer insulation layer 25 covers and protects the stacked body 20, the vias 28, the wirings 23, and the wirings 24. For the interlayer insulation layer 25, an insulation layer such as a silicon oxide film including silicon and oxygen.

The interlayer insulation layer 25 and the interlayer insulation layer 35 are bonded to each other on the bonding surface B1, and the wirings 24 and the wirings 34 are also joined at the bonding surface B1. Thus, the array chip 2 and the CMOS chip 3 are electrically connected to each other via the wirings 24 and the wirings 34.

FIG. 2 is a schematical plane view illustrating the stacked body 20. The stacked body 20 includes two stepped portions 2s on either side of the memory cell array 2m. The stepped portions 2s are provided at the ends of the stacked body 20 in the Y direction. The memory cell array 2m is located between the stepped portions 2s. The slit ST extends from the stepped portion 2s at one end of the stacked body 20, through the memory cell array 2m, to the stepped portion 2s at the other end of the stacked body 20. A slit SHE is provided in the memory cell array 2m. The slit SHE is shallower than the slit ST in the Z direction, and extends substantially parallel to the slit ST. The slit SHE is provided electrically isolate the electrode layers 21 corresponding to the drain side select gate SGD on either side of the slit SHE. Alternatively, as described above, the slit ST may be include a source wiring that is electrically connected to the source layer BSL and electrically isolated from the electrode layers 21 of the stacked body 20.

A part of the stacked body 20 between two slits ST illustrated in FIG. 2 is called a block (BLOCK). The block is a minimum unit of data erasure. The slit SHE is provided in the block. The stacked body 20 between the slit ST and the slit SHE is called a finger. The drain side select gate SGD is divided for each finger. Therefore, when writing and reading data, one finger in the block can be brought into a selected state by the drain side select gate SGD.

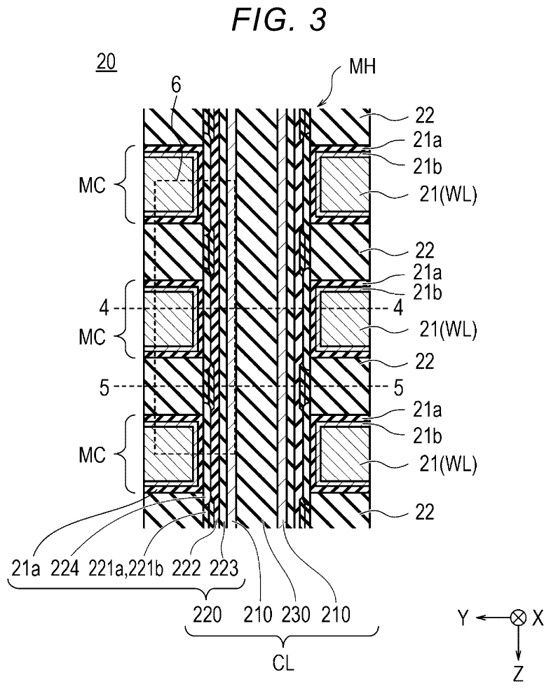

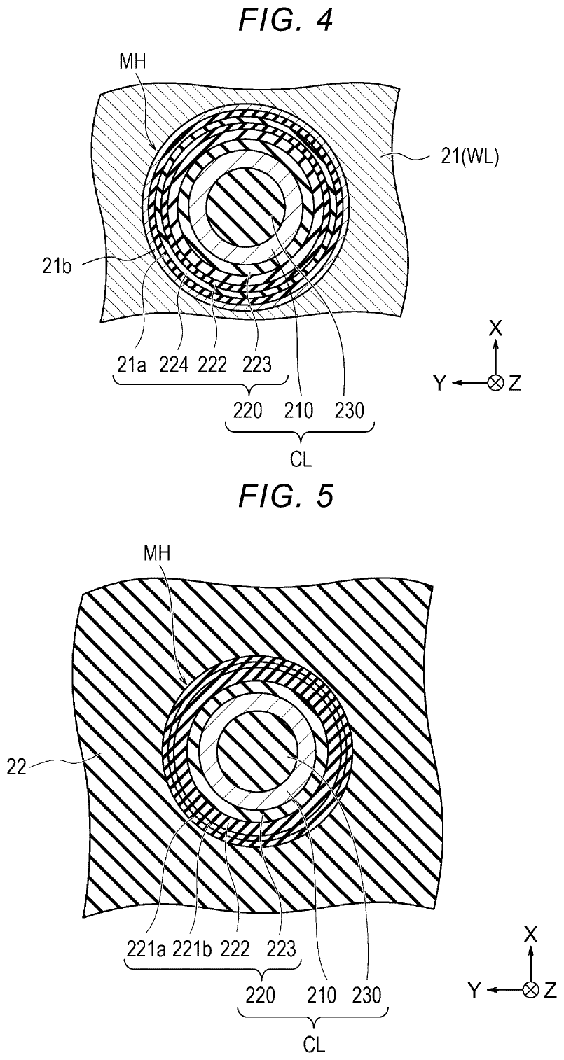

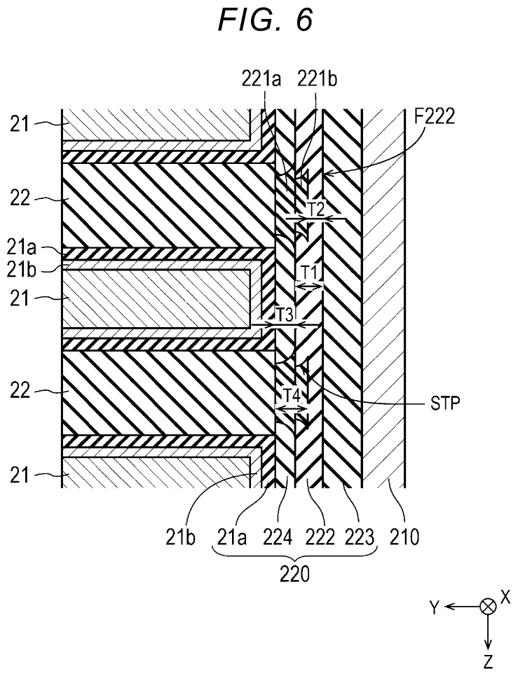

Each of FIG. 3 to FIG. 6 is a schematical cross-sectional view of the memory cell array of the array chip 2. FIG. 4 illustrates a cross section along a line 4-4 in FIG. 3 and FIG. 5 illustrates a cross section along a line 5-5 in FIG. 3. FIG. 6 illustrates an enlarged cross section of an area encircled with a dashed line frame 6 in FIG. 3.

As illustrated in FIG. 3, each of the plurality of columnar bodies CL is provided in a memory hole MH provided in the stacked body 20. Each columnar body CL penetrates the stacked body 20 from the top end of the stacked body 20 along the Z direction so as to be provided in the stacked body 20 and the source layer BSL. Each of the plurality of columnar bodies CL includes the semiconductor body 210, a memory film 220, and a core layer 230. The core layer 230 is provided in the center of the columnar body CL. The semiconductor body (which is a semiconductor layer) 210 is provided around the core layer 230, and the memory film 220 is provided around the semiconductor body 210. The semiconductor body 210 extends in the stacked body 20 in the stacking direction (Z direction). The semiconductor body 210 is electrically connected to the source layer BSL. The memory film 220 is provided between the semiconductor body 210 and the electrode layers 21, and includes a charge trapping layer. The columnar bodies CL corresponding to one finger are each connected to one bit line BL through the vias 28 in FIG. 1. Each of the columnar bodies CL is provided in a region of the memory cell array 2m, for example.

As illustrated in FIG. 3 and FIG. 6, a block insulation layer 21a and a barrier film 21b in the memory film 220 are provided between the electrode layers 21 and the insulation layers 22 and between the electrode layers 21 and a block insulation layer 224. The block insulation layer 21a is, for example, silicon oxide or metal oxide. One example of the metal oxide is aluminum oxide including aluminum and oxygen. For the barrier film 21b, when the electrode layers 21 are made of tungsten, a stacked film with titanium nitride and titanium is selected, for example. The block insulation layer 21a controls back-tunneling of charge from the electrode layers 21 to the memory film 220 side. The barrier film 21b is a conductive material that improves the adhesion between the electrode layers 21 and the block insulation layer 21a. For the barrier film 21b, a conductive metal compound such as a stacked film with titanium nitride and titanium is used.

As illustrated in FIG. 4 and FIG. 5, the shape of the memory hole MH on a X-Y plane surface is circular or elliptical. As illustrated in FIG. 4, the core layer 230 is in the center of the memory hole MH, and the semiconductor body 210 and the memory film 220 are provided around the core layer 230.

The shape of the semiconductor body 210 is a cylindrical shape having a bottom, for example. For the semiconductor body 210 polysilicon is used, for example. The semiconductor body 210 is, for example, undoped silicon. In addition, the semiconductor body 210 may be a p-type silicon. The semiconductor body 210 forms a channel for each of the drain side select transistor STD, the memory cell MC, and the source side select transistor STS. One ends of a plurality of the semiconductor bodies 210 in the same memory cell array 2m are electrically connected to the source layer BSL in common.

The memory film 220 is provided between the inner wall of the memory hole MH and the semiconductor body 210. The shape of the memory film 220 is a cylindrical shape, for example. A plurality of the memory cells MC has a storage region between the semiconductor body 210 and the electrode layers 21 functioning as word lines WL, and is stacked on top of each other in the Z direction. The memory film 220 includes the block insulation layers 21a and 224, cover insulation layers 221a and 221b, a charge trapping film 222, and a tunnel insulation layer 223, for example. The semiconductor body 210, the charge trapping film 222, and the tunnel insulation layer 223 extend in the Z direction.

As illustrated in FIG. 5 and FIG. 6, the cover insulation layers 221a and 221b are provided between the insulation layer 22 and the charge trapping film 222. As illustrated in FIG. 5, in the memory hole MH, around the charge trapping film 222, the cover insulation layer 221a is provided. Around the cover insulation layer 221a, the cover insulation layer 221b is provided. For the cover insulation layers 221a and 221b, an insulation layer such as silicon oxide including silicon and oxygen is used. The cover insulation layers 221a and 221b protect the charge trapping film 222 from being etched when sacrificial layers (not illustrated) are replaced with the electrode layers 21 (replacement process).

As illustrated in FIG. 4 and FIG. 6, the block insulation layer 224 is provided between the electrode layers 21 and the charge trapping film 222. The block insulation layer 224 controls back-tunneling of charge from the electrode layers 21 to the memory film 220 side together with the block insulation layer 21a.

The charge trapping film 222 is provided between the stacked body 20 and the tunnel insulation layer 223. The charge trapping film 222 is provided between the cover insulation layers 221a and 221b and the tunnel insulation layer 223 and between the block insulation layer 224 and the tunnel insulation layer 223. As illustrated in FIG. 6, a thickness T1 of the charge trapping film 222 between the electrode layer 21 and the tunnel insulation layer 223 is thicker than a thickness T2 of the charge trapping film 222 between the insulation layer 22 and the tunnel insulation layer 223. In addition, in a step region STP where the thickness of the charge trapping film 222 changes, the charge trapping film 222 is constricted in the radial direction of the memory hole MH (Y direction and X direction). The side wall of the step region STP of this charge trapping film 222 is inclined with respect to the Z direction, the Y direction, and the X direction, and is formed in a taper shape, i.e. tapered. The term “tapered” means to be inclined with respect to any of the Z direction, X direction, and Y direction. In addition, the “tapered” surface is not necessarily a plane surface, and it may include a curved surface.

As illustrated in FIG. 6, in the step region STP where the thickness of the charge trapping film 222 changes, the cover insulation layer 221b is embedded in a constricted portion of the charge trapping film 222. Therefore, a total thickness T4 of the cover insulation layers 221a and 221b in the Y direction is thicker than a thickness T3 of the block insulation layer 224 in the Y direction. Thus, a side surface F222 of the charge trapping film 222 at the center side of the memory hole MH is substantially flat along the side wall of the memory hole MH. That is, the side surface of the charge trapping film 222 at the center side of the memory hole MH is not constricted and does not protrude in the Y direction and the X direction. With this configuration, the semiconductor body 210 and the tunnel insulation layer 223 are also substantially flat along the side wall of the memory hole MH, are not constricted, and do not protrude in the Y direction and the X direction.

The cover insulation layer 221b is embedded in the constricted portion of the charge trapping film 222, and thus the both side surfaces of the cover insulation layer 221b in the Z direction are formed in a taper shape inclined with respect to the Z direction, the Y direction, and X direction corresponding to the side wall of the step region STP of the charge trapping film 222.

The cover insulation layer 221a is provided between the cover insulation layer 221b and the insulation layer 22, and is provided between the block insulation layers 224 adjacent in the Z direction. Both side surfaces of the block insulation layer 224 in the Z direction are also formed in a taper shape inclined with respect to the Z direction, the Y direction, and the X direction. Also, both side surfaces of the cover insulation layer 221a in the Z direction are formed in a taper shape inclined with respect to the Z direction, the Y direction, and X direction corresponding to the side wall of the block insulation layer 224.

For the block insulation layer 224 and the cover insulation layer 221a, a silicon oxide film is used, for example. For example, the density (g/cm³) of each of the block insulation layer 224 and the cover insulation layer 221a is lower than the density of the cover insulation layer 221b.

For the charge trapping film 222, an insulation layer such as silicon nitride including silicon and nitrogen is used. The charge trapping film 222 has a trap region where charges are trapped. A relatively thick portion of the charge trapping film 222 interposed between the electrode layers 21 functioning as word lines WL and the semiconductor body 210 make up a charge storage trapping portion of the memory cell MC. The threshold voltage of the memory cell MC changes depending on the presence or absence of charges in the charge trapping portion or the amount of the charges trapped in the charge trapping portion. The memory cell MC stores information in accordance with the amount of the charges trapped in its charge trapping portion.

The tunnel insulation layer 223 is provided between the stacked body 20 and the semiconductor body 210. More specifically, the tunnel insulation layer 223 is provided between the semiconductor body 210 and the charge trapping film 222. For the tunnel insulation layer 223, an insulation layer such as silicon oxide including silicon and oxygen or a silicon oxynitride film including silicon oxide and silicon nitride is used. The tunnel insulation layer 223 is a potential barrier between the semiconductor body 210 and the charge trapping film 222. For example, when an electron is injected from the semiconductor body 210 into the charge trapping film 222 (e.g., during a writing operation), and when an electron hole is injected from the semiconductor body 210 into the charge trapping film 222 (e.g., during an erasing operation), the electron and the electron hole pass through the potential barrier of the tunnel insulation layer 223. The effect is known as tunneling.

The core layer 230 is embedded in the internal space of the cylindrical semiconductor body 210. The shape of the core layer 230 is a column shape. For the core layer 230, an insulation layer such as silicon oxide including silicon and oxygen is used.

According to the present embodiment, the thickness T2 of the charge trapping film 222 is relatively thin and the charge trapping film 222 has a constricted portion between the insulation layer 22 and the tunnel insulation layer 223. The cover insulation layers 221a and 221b are embedded in the constricted portion of the charge trapping film 222. Thus, the charge accumulated in the charge trapping layer 222 facing the electrode layers 21 in the Y direction are isolated to some extent by the constricted portion in the Z direction. That is, the constricted portion makes it difficult for the charge accumulated in the charge trapping film 222 corresponding to one memory cell MC to move to the other memory cells MC that are adjacent in the Z direction. As a result, deterioration of data storage characteristics can be suppressed.

The thickness T1 of the charge trapping film 222 between the electrode layers 21 and the tunnel insulation layer 223 is relatively thick, and accordingly, the thickness of the block insulation layer 224 is thin. Therefore, the thickness of the block insulation layers 21a, 224 and the charge trapping film 222 between the electrode layers 21 and the tunnel insulation layer 223 can be substantially the same as the thickness of the cover insulation layers 221a and 221b and the charge trapping film 222 between the insulation layer 22 and the tunnel insulation layer 223. Thus, the side surface F222 of the charge trapping film 222 is substantially planarized along the inner wall of the memory hole MH. As a result, the tunnel insulation layer 223 and the semiconductor body 210 deposited on the side surface F222 of the charge trapping film 222 are also substantially flat and conformally formed along the inner wall of the memory hole MH. That is, the tunnel insulation layer 223 and the semiconductor body 210 are not constricted and do not protrude in the X direction or the Y direction. Therefore, the resistance of the semiconductor body 210 remains almost unchanged at any position of the Z direction and a local reduction in a cell current flowing in the memory cell MC can be prevented.

In addition, the thickness T1 of the charge trapping film 222 between the electrode layer 21 and the tunnel insulation layer 223 is relatively thick, and thus the charge trapping film 222 corresponding to each memory cell MC can sufficiently accumulate charge.

In addition, not only the block insulation layer 21a but also the block insulation layer 224 is provided between the electrode layers 21 and the charge trapping film 222. Accordingly, tunneling of the charge accumulated in the charge trapping film 222 to the electrode layers 21 is suppressed and back-tunneling of the charge from the electrode layer 21 to the memory film 220 side also can be suppressed.

Next, a method of manufacturing the semiconductor storage device 1 according to the present embodiment will be described.

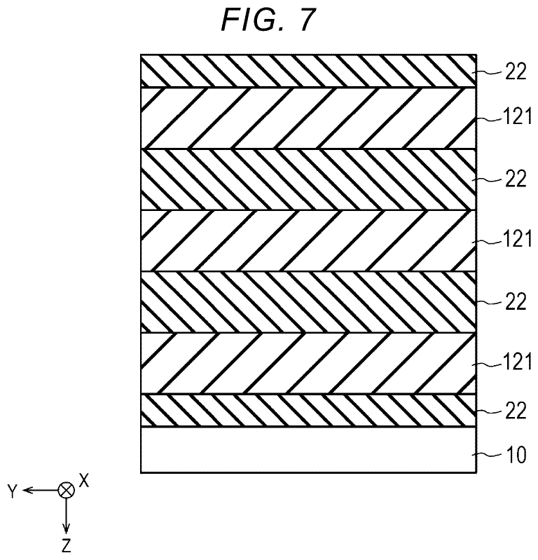

FIG. 7 to FIG. 15 are cross-sectional views illustrating an example of a method of manufacturing the array chip 2 according to the first embodiment.

As illustrated in FIG. 7, using a chemical vapor deposition (CVD) method, for example, the insulation layers 22 and sacrificial layers 121 are alternately stacked on a semiconductor substrate 10 in the Z direction. Thus, the stacked body 20 having layers stacked in the Z direction is formed. Each insulation layer 22 is, for example, a silicon oxide layer. Each sacrificial layer 121 is, for example, an insulation layer such as a silicon nitride layer including silicon and nitrogen. The sacrificial layers 121 are replaced with a material for the electrode layers 21 in a subsequent process. The insulation layers 22 are each an interlayer insulation layer between the electrode layers 21.

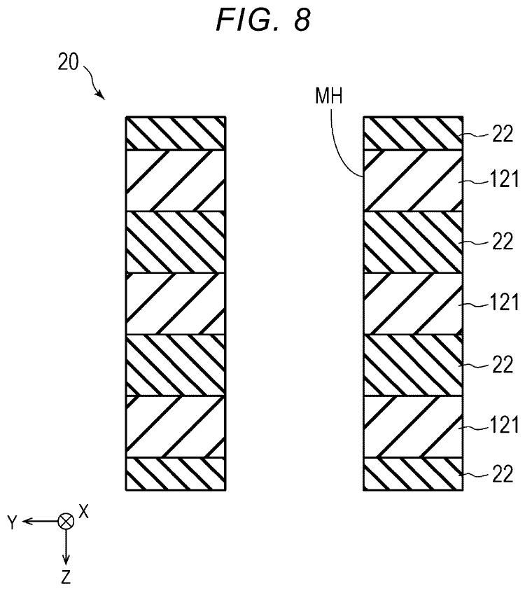

As illustrated in FIG. 8, for example, using lithography technique and a reactive ion etching (RIE) method, the memory hole MH extending in the stacked body 20 along the Z direction is formed. In the drawings from FIG. 8, the semiconductor substrate 10 is omitted. The memory hole MH penetrates the stacked body 20 including the insulation layers 22 and the sacrificial layers 121.

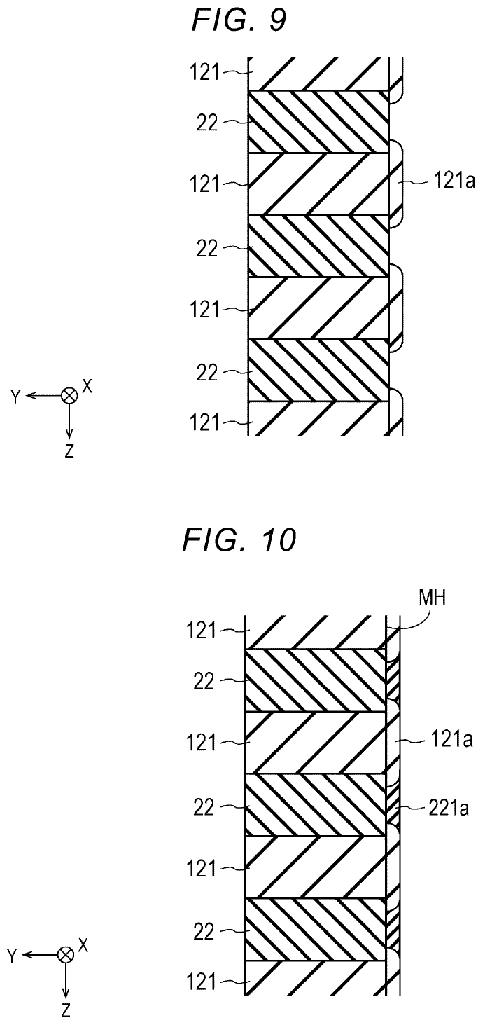

As illustrated in FIG. 9, sacrificial layers 121a are formed on the sacrificial layers 121 exposed on the inner wall of the memory hole MH using a selective growth method. Each sacrificial layer 121a is, for example, an insulation layer such as silicon nitride film including silicon and nitrogen. The sacrificial layers 121a are selectively formed on the exposed surface of the sacrificial layers 121 without being formed on the insulation layers 22. For example, at a low temperature of about four hundred fifty degrees, gas including a halogen, for example, SiHX₃, SiX₄(X=F, Cl, Br, I) or the like is introduced into the memory hole MH and selectively absorbed on the exposed surface of the insulation layers 22. This prevents the growth of Si precursor, for example, dichlorosilane SiH₂Cl₂ or hexachlorodisilane Si₂Cl₆ on the insulation layer 22 to avoid film formation of silicon nitride on the insulation layer 22 and to cause the precursor to be absorbed on the exposed surface of the sacrificial layers 121. Thus, the sacrificial layer 121a is selectively deposited on the exposed surface of the sacrificial layers 121. In this process, the sacrificial layers 121a are isotropically formed, and thus each sacrificial layer 121a has inclinations on both side surfaces thereof in the Z direction.

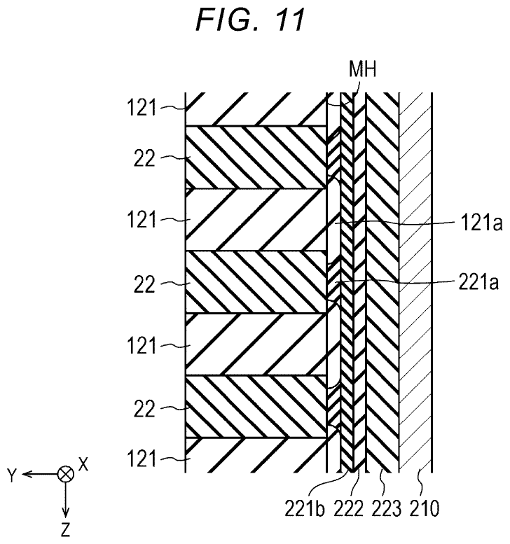

As illustrated in FIG. 10, the cover insulation layers 221a are formed on the insulation layers 22 exposed on the inner wall of the memory hole MH using the selective growth method. Each cover insulation layer 221a is, for example, an insulation layer such as a silicon oxide film including silicon and oxygen. The cover insulation layers 221a are selectively formed on the exposed surface of the insulation layers 22 without being formed on the sacrificial layers 121a. For example, an inhibitor that prevents the growth of Si precursor on the sacrificial layers 121a, for example, gas including Si, such as dichlorosilane SiH₂Cl₂ or hexachlorodisilane Si₂Cl₆, is introduced into the memory hole MH and selectively absorbed on the exposed surface of the sacrificial layers 121a. This avoids film formation of a silicon oxide film on the sacrificial layers 121a and causes the precursor to be absorbed on the insulation layers 22. Thus, the cover insulation layers 221a are selectively deposited on the insulation layers 22. In this process, each cover insulation layer 221a is formed to be embedded between the sacrificial layers 121a adjacent in the Z direction. Therefore, each cover insulation layer 221a has inclinations on both side surfaces thereof in the Z direction along the side surfaces of the adjacent sacrificial layers 121a, so as to be formed in a taper shape. In addition, the cover insulation layers 221a and the sacrificial layers 121a are formed to be substantially flat in the vertical direction inside the memory hole MH.

As illustrated in FIG. 11, in the memory hole MH, each material for the cover insulation layer 221b, the charge trapping film 222, the tunnel insulation layer 223, and the semiconductor body 210 is formed in this order on the cover insulation layers 221a and the sacrificial layers 121a. Each material for the cover insulation layer 221b, the charge trapping film 222, the tunnel insulation layer 223, and the semiconductor body 210 is deposited using, for example, an atomic layer deposition (ALD) method or the CVD method. The cover insulation layer 221b and the tunnel insulation layer 223 are insulation layers such as silicon oxide films including silicon and oxygen. The tunnel insulation layer 223 may be a silicon oxynitride layer including silicon, oxygen, and nitrogen. The semiconductor body 210 is a semiconductor layer including a semiconductor such as polysilicon. The charge trapping film 222 is an insulation layer such as a silicon nitride film including silicon and nitrogen. As shown in FIG. 11, the cover insulation layer 221a and the sacrificial layer 121a are substantially flat in the vertical direction inside the memory hole MH, and thus on the cover insulation layers 221a and the sacrificial layers 121a, the materials for the cover insulation layer 221b, the charge trapping film 222, the tunnel insulation layer 223, and the semiconductor body 210 are formed to be substantially flat in the vertical direction inside the memory hole MH and to make the film thicknesses substantially uniform.

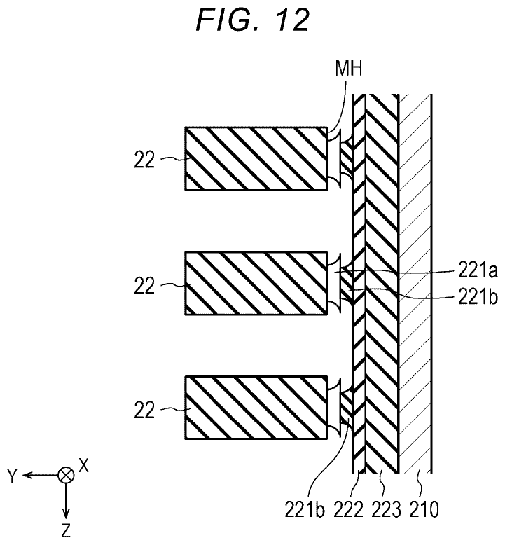

In illustrated in FIG. 12, using solution containing phosphoric acid or gas, the sacrificial layers 121 and 121a are selectively etched and removed. As a result, the cover insulation layer 221b is exposed in the space after the sacrificial layers 121 and 121a are removed. The cover insulation layer 221b functions as an etch stopper to protect the charge trapping film 222. In addition, the insulation layers 22 and the cover insulation layers 221a are left.

Then, using solution containing hydrofluoric acid or gas, the cover insulation layer 221b is isotropically etched. As a result, the cover insulation layer 221b is selectively removed and the charge trapping film 222 is exposed in the space after the sacrificial layers 121 and 121a are removed. In this process, a part of the cover insulation layer 221b is left between the cover insulation layer 221a and the charge trapping film 222. In addition, the cover insulation layer 221b is isotropically etched, and thus has inclinations on its side surfaces in the Z direction.

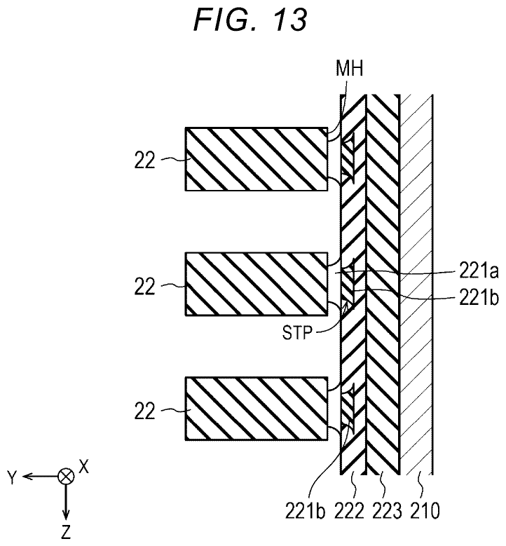

As illustrated in FIG. 13, on the surface of the charge trapping film 222 exposed in the above-described space, a material for the charge trapping film 222 (for example, an insulation layer such as a silicon nitride film including silicon and nitrogen) is further deposited. In this process, using the selective growth method described with reference to FIG. 9, the material for the charge trapping film 222 is additionally deposited on the surface of the charge trapping film 222. The charge trapping film 222 is formed to be embedded between the cover insulation layers 221b that are adjacent in the Z direction. Therefore, the charge trapping film 222 grows along the side surfaces of the cover insulation layers 221b having a taper. Accordingly, the charge trapping film 222 has inclinations where it contacts the side surfaces of the cover insulation layers 221b in the Z direction that are formed in a taper shape. In addition, in the Y direction, the thickness of the charge trapping film 222 between the above-described space and the tunnel insulation layer 223 is thicker than the thickness of the charge trapping film 222 between the insulation layer 22 and the tunnel insulation layer 223. In each step region STP where the thickness of the charge trapping film 222 changes, the charge trapping film 222 has an inclination. Meanwhile, the cover insulation layer 221b has an inclination in the side surface thereof corresponding to the step region STP.

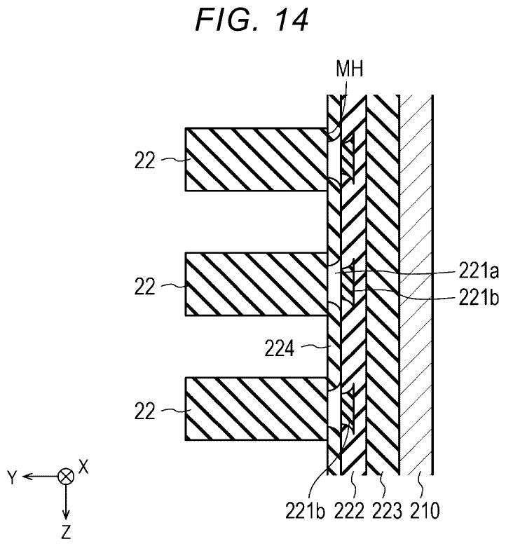

As illustrated in FIG. 14, on the surface of the cover insulation layers 221a exposed in the above-described space, the material for the block insulation layer 224 (for example, an insulation layer such as a silicon oxide film including silicon and oxygen) is deposited. At this time, using the selective growth method described with reference to FIG. 10, the material for the block insulation layer 224 is additionally deposited on the surface of the charge trapping film 222. The density (g/cm³) of each of the block insulation layer 224 and the cover insulation layer 221a is lower than the density of the cover insulation layer 221b.

The block insulation layer 224 is formed to be embedded between the cover insulation layers 221a adjacent in the Z direction. Therefore, the block insulation layer 224 grows along the side surface of the cover insulation layer 221a having a taper and has corresponding inclinations along these side surfaces of the cover insulation layer 221a in the Z direction. In addition, the total thickness of the cover insulation layers 221a and 221b in the Y direction is thicker than that of the block insulation layer 224.

As illustrated in FIG. 15, on the surfaces of the block insulation layer 224 exposed in the above-described space and the insulation layer 22, the material for the block insulation layer 21a (for example, an insulation layer such as an aluminum oxide film including aluminum and oxygen) is deposited. Then, on the surface of the block insulation layer 21a exposed in the above-described space, the material for the barrier film 21b (for example, a stacked film with titanium nitride and titanium, or a single layer film) is deposited.

As illustrated in FIG. 6, the material for the electrode layers 21 (for example, tungsten) is embedded inside the block insulation layer 21a in the above-described space. Through such a replacement process, the sacrificial layers 121 are replaced with the electrode layers 21.

Subsequently, the vias 28, the wirings 24, and the like are formed and then the array chip 2 is completed. Separately from the array chip 2, the CMOS chip 3 is formed. The array chip 2 and the CMOS chip 3 are bonded to each other on the bonding surface B1. Thereafter, the metal layer 40, the bonding pad 50 and the like are formed and then the semiconductor storage device 1 is completed.

According to the embodiment as described above, the charge trapping film 222 is selectively grown additionally to be thick between the electrode layers 21 and the tunnel insulation layer 223. In addition, the cover insulation layers 221a are selectively grown, and the cover insulation layers 221a and 221b are thereby formed to be relatively thick between the insulation layer 22 and the tunnel insulation layer 223. Thus, the charge trapping film 222 corresponding to each memory cell MC is formed to be thick and a constricted portion is formed in the charge trapping film 222 between the memory cells MC. Thus, the constricted portion makes it difficult for the charge accumulated in the charge trapping film 222 of one memory cell MC to migrate to the charge trapping film 222 of the other memory cells MC adjacent in the Z direction. That is, the memory cells MC adjacent in the Z direction are substantially isolated. As a result, deterioration of data storage characteristics can be suppressed.

In addition, the charge trapping film 222 is selectively grown to be relatively thick between the electrode layers 21 and the tunnel insulation layer 223. The cover insulation layers 221a are selectively grown, and the cover insulation layers 221a and 221b are thereby formed to be relatively thick between the insulation layers 22 and the tunnel insulation layer 223. Thus, the side surface F222 of the charge trapping film 222 is substantially planarized along the inner wall of the memory hole MH. As a result, the tunnel insulation layer 223 and the semiconductor body 210 deposited on the side surface F222 of the charge trapping film 222 are also conformally formed in the vertical direction along the inner wall of the memory hole MH. Therefore, a local reduction in a cell current flowing in the memory cell MC can be prevented.

### Second Embodiment

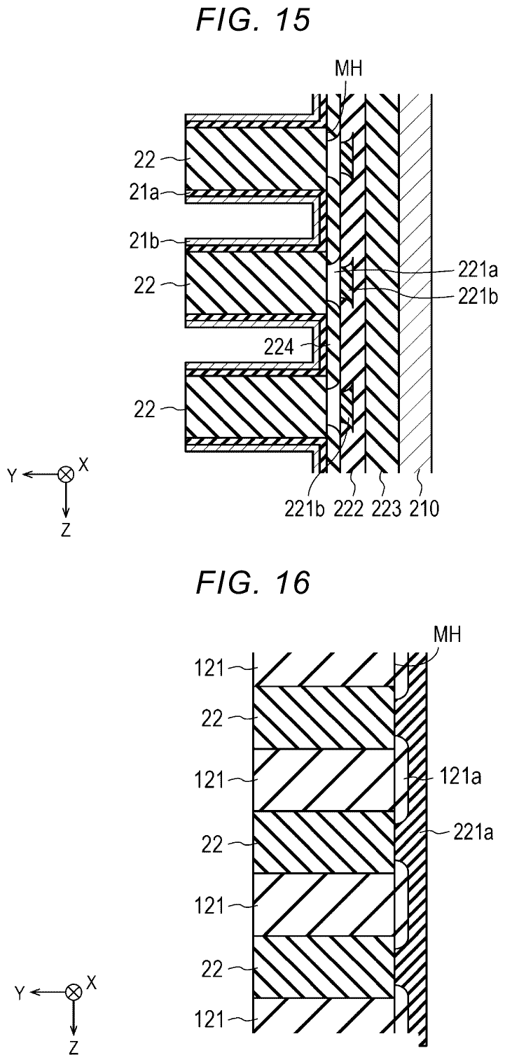

FIG. 16 is a cross-sectional view illustrating an example of a method of manufacturing the array chip 2 according to a second embodiment. The second embodiment is different from the first embodiment in a forming method of the cover insulation layer 221a.

After performing the processes described with reference to FIG. 7 to FIG. 9, as illustrated in FIG. 16, using the ALD method or the CVD method, the material for the cover insulation layers 221a is deposited on the entire inner wall of the memory hole MH.

Using a wet etching method or a chemical dry etching (CDE) method, the material for the cover insulation layers 221a is isotropically etched back. As a result, the sacrificial layers 121a are exposed on the inner wall of the memory hole MH and the cover insulation layers 221a are selectively left on the insulation layers 22. In this manner, the cover insulation layers 221a illustrated in FIG. 10 may be formed.

Subsequently, after performing the processes described with reference to FIG. 11 to FIG. 15, the structure illustrated in FIG. 6 is obtained.

The other manufacturing processes and configurations of the second embodiment may be the same as those of the first embodiment. Accordingly, in the second embodiment, the same effect as that of the first embodiment can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a stacked body in which electrode layers and first insulation layers are alternately stacked in a first direction;
a semiconductor layer extending through the stacked body along the first direction;
a second insulation layer extending in the first direction and provided between the stacked body and the semiconductor layer;
a third insulation layer extending in the first direction and provided between the stacked body and the second insulation layer, wherein a first thickness of the third insulation layer in a second direction perpendicular to the first direction between the electrode layers and the second insulation layer is thicker than a second thickness of the third insulation layer in the second direction between the first insulation layers and the second insulation layer, the third insulation layer being inclined with respect to the first direction in a step region of the third insulation layer where the thickness thereof changes from the first thickness to the second thickness;
fourth insulation layers provided between the electrode layers and the third insulation layer; and
a fifth insulation layer provided between a first electrode layer, which is one of the electrode layers, and the first insulation layers adjacent to the first electrode layer and between the first electrode layer and one of the fourth insulation layers.

2. The semiconductor storage device according to claim 1, further comprising:
sixth and seventh insulation layers provided between one of the first insulation layers and the third insulation layer, wherein
a thickness of the sixth and seventh insulation layers in the second direction is thicker than a thickness of the fourth insulation layers in the second direction.

3. The semiconductor storage device according to claim 2, wherein
the sixth insulation layer is provided between the seventh insulation layer and one of the first insulation layers, and is provided between the fourth insulation layers adjacent thereto in the first direction.

4. The semiconductor storage device according to claim 2, wherein
the seventh insulation layer is embedded in a constricted portion of the third insulation layer having the second thickness.

5. The semiconductor storage device according to claim 4, wherein
the seventh insulation layer is inclined with respect to the first direction on a side thereof in contact with the step region of the third insulation layer.

6. The semiconductor storage device according to claim 2, wherein
the third insulation layer is an insulation layer including silicon and nitrogen,
the fourth, sixth, and seventh insulation layers are insulation layers including silicon and oxygen, and
the fifth insulation layer is an insulation layer including silicon and aluminum.

7. The semiconductor storage device according to claim 6, wherein
the fourth insulation layer has a density that is lower than a density of the seventh insulation layer.

8. A method of manufacturing a semiconductor storage device comprising:
forming a stacked body by stacking sacrificial layers and first insulation layers alternately in a first direction;
forming a hole extending through the stacked body in the first direction;
selectively depositing a material for the sacrificial layers on each of the sacrificial layers in the hole;
selectively forming second insulation layers on the first insulation layers in the hole;
forming a third insulation layer, a fourth insulation layer, a fifth insulation layer, and a semiconductor layer in this order on the sacrificial layers and the second insulation layers in the hole;
removing the sacrificial layers from the stacked body;
removing the third insulation layer exposed in a space after the sacrificial layers are removed to expose the fourth insulation layer in the space;
depositing a material for the fourth insulation layer on the fourth insulation layer exposed in the space;
forming sixth insulation layers between the second insulation layers and on the fourth insulation layer exposed in the space;
forming seventh insulation layers on the first insulation layers and the sixth insulation layers in the space; and
forming electrode layers on the seventh insulation layers.

9. The method according to claim 8, wherein forming the electrode layers include:
depositing a barrier metal on the seventh insulation layers; and
depositing a material for the electrode layers on the barrier metal.

10. The method according to claim 8, further comprising:
prior to selectively depositing the material for the sacrificial layers on each of the sacrificial layers in the hole, introducing into the hole a gas including a halogen that is selectively absorbed on surfaces of the first insulation layers.

11. The method according to claim 10, wherein the material for the sacrificial layers deposited on the sacrificial layers forms additional sacrificial layers.

12. The method according to claim 11, wherein the additional sacrificial layers are formed isotropically to have inclinations on both side surfaces thereof in the first direction.

13. The method according to claim 12, wherein
each of the second insulation layers is formed on one of the first insulation layers in the hole and between the additional sacrificial layers that are adjacent thereto in the first direction.

14. The method according to claim 8, wherein the sacrificial layers are removed from the stacked body by selective etching.

15. The method according to claim 14, wherein the third insulation layer is an etch stopper during the selective etching.

16. The method according to claim 15, wherein the third insulation layer exposed in the space after the sacrificial layer is removed, is removed by etching, and the etching does not remove the third insulation layer covered by the second insulation layers.

17. A method of manufacturing a semiconductor storage device comprising:
forming a stacked body by stacking sacrificial layers and first insulation layers alternately in a first direction;
forming a hole extending through the stacked body in the first direction;
selectively depositing a material for the sacrificial layers on each of the sacrificial layers in the hole to form additional sacrificial layers that protrude from the sacrificial layers;
depositing a second insulation layer on the additional sacrificial layers and first insulation layers and etching the second insulation layer until the additional sacrificial layers are exposed and portions of the second insulation layer separated by the additional sacrificial layers in the first direction remain;
forming a third insulation layer, a fourth insulation layer, a fifth insulation layer, and a semiconductor layer in this order on the sacrificial layers and the second insulation layers in the hole;
removing the sacrificial layers from the stacked body;
removing the third insulation layer exposed in a space after the sacrificial layers are removed to expose the fourth insulation layer in the space;
depositing a material for the fourth insulation layer on the fourth insulation layer exposed in the space;
forming sixth insulation layers between the remaining portions of the second insulation layer and on the fourth insulation layer exposed in the space;
forming seventh insulation layers on the first insulation layers and the sixth insulation layers in the space; and
forming electrode layers on the seventh insulation layers.

18. The method according to claim 17, wherein forming the electrode layers include:
depositing a barrier metal on the seventh insulation layers; and
depositing a material for the electrode layers on the barrier metal.

19. The method according to claim 17, further comprising:
prior to selectively depositing the material for the sacrificial layers on each of the sacrificial layers in the hole, introducing into the hole a gas including a halogen that is selectively absorbed on surfaces of the first insulation layers.

20. The method according to claim 17, wherein the sacrificial layers are removed from the stacked body by selective etching and the third insulation layer is an etch stopper during the selective etching.
